(19) United States
(12) Patent Application Publication
(10) Pub. No.: US 2004/0105225 A1
(43) Pub. Date: Jun. 3, 2004

(54) Multi-drive carrier

(76) Inventors: Tom Reeves Malcolm, Colorado Springs, CO (US); Timothy Gene Lieber, Colorado Springs, CO (US)

Correspondence Address: OPPEDAHL AND LARSON LLP, P O BOX 5068, DILLON, CO, 80435-5068, US

(21) Appl. No.: 10/604,759

(22) Filed: Aug. 14, 2003

Related U.S. Application Data
(60) Provisional application No. 60/403,785, filed on Aug. 14, 2002.

(51) Int. Cl. H05K 5/00

(52) U.S. Cl. 361/683

(57) ABSTRACT

A rack-mounted disk drive enclosure has a plurality of frames, each capable of being individually pulled out of the enclosure from the front. Each frame is L shaped and has a vertical portion that is more or less planar as well as a horizontal portion carrying circuitry, for example in a printed circuit board. Each frame carries a plurality of disk drives, each having at least one platter spinning parallel with the vertical portion of the frame. Each drive is disposed with its connector pointing downward, toward the printed circuit board and plugged thereinto. At the rear of the frame, a connector connects to a centerplane. Concentrator logic is placed on the printed circuit board of the frame, as are LEDs or other indicators permitting an indication of which drive (if any) needs to be replaced. In this way, it is possible to remove more than one drive, and let less than all of the drives, at a time, from the enclosure, while other drives can remain in service.

### CROSS REFERENCE TO RELATED APPLICATIONS

This application claims priority from U.S. application No. 60/403,785 filed Aug. 14, 2002, which application is incorporated herein by reference for all purposes.

### BACKGROUND OF INVENTION

Many conflicting demands conspire to make it difficult to design storage enclosures for hard disk drives. For a number of reasons, including a need for fast and low-latency data retrieval as well as a need for redundant storage, customer demands require enclosure designers to find ways to fit large numbers of disk drives into the enclosures. In response to customer requirements, many present-day storage enclosures are rack meeting mechanical mounting requirements well known to those skilled in the art. Rack mounting offers many advantages including the opportunity for dense packing of the equipment.

A present-day storage enclosure provides high reliability and MTBF through, among other things, making use of a large number of drives and storing data on the drives in such a way that if any one drive were to fail, no data would be lost and the system would seamlessly continue its function by means of the many remaining drives in the enclosure. All assumptions regarding reliability and performance, however, presume that any one malfunctioning drive will be replaced quite soon after it has failed.

Designers of prior-art enclosures have addressed this need in several ways. Some enclosures simply require that the user remove the enclosure from the rack, open a lid, replace a drive, and replace the enclosure in the rack. This is time-consuming and awkward. Other enclosures use slides to permit sliding the enclosure out from the rack so that a lid can be opened. This devotes some non-negligible portion of the width budget to slides and associated hardware, and thus reduces the portion of the width that can be allocated to productive payload (that is, more disk drives). Still other enclosures use a horizonal chassis or mounting board that is supposed to slide out the front of the housing, carrying all of the disk drives. The user then removes the errant drive from the chassis or board, plugs in a new one, and slides the chassis or board back into place. This has a drawback that all drives are out of service for the interval during which the chassis or board is “out.” Still other enclosures have a series of vertical cards, each carrying one or more drives. Each card plugs into a backplane and can be slid out the front of the enclosure for service. In this arrangement, each drive is plugged into its own connector on the backplane independent of any other drives. This has a drawback in that the backplane is not a field-replaceable unit—the enclosure must at a minimum be removed from the rack, and in many cases fully disassembled, to gain access to the backplane if it needs to be replaced. Such a backplane is typically vertical and is parallel to the front face of the enclosure, and is as tall as the enclosure. As such, it is a barrier to the flow of cooling air between fans (located at the rear of the enclosure) and drives (located at the front of the enclosure).

There is thus a need for an enclosure design that avoids these various drawbacks and permits ready replacement of any particular drive. It would be highly desirable to arrive at a design which:—provides a way to access the large number of hard drives from the front of the enclosure without having to slide an entire shelf out for hard drive access;—solves the problem of making the backplane a field replaceable unit;—improves airflow through the enclosure due to the elimination of a vertically arranged backplane; and—significantly reduces backplane size and routing complexity.

### SUMMARY OF INVENTION

A rack-mounted disk drive enclosure has a plurality of frames, each capable of being individually pulled out of the enclosure from the front. Each frame is L shaped and has a vertical portion that is more or less planar as well as a horizontal portion carrying circuitry, for example in a printed circuit board. Each frame carries a plurality of disk drives, each having at least one platter spinning parallel with the vertical portion of the frame. Each drive is disposed with its connector pointing downward, toward the printed circuit board and plugged thereinto. At the rear of the frame, a connector connects to a centerplane. Concentrator logic is placed on the printed circuit board of the frame, as are LEDs or other indicators permitting an indication of which drive (if any) needs to be replaced. In this way, it is possible to remove more than one drive, and let less than all of the drives, at a time, from the enclosure, while other drives can remain in service.

### BRIEF DESCRIPTION OF DRAWINGS

FIG. 1 shows a side cutaway view of an enclosure according to the invention;

FIG. 2a is a front view of a frame according to the invention;

FIG. 2b is a close-up front view of the frame of FIG. 2a;

FIG. 3a is a rear view of a frame according to the invention; and

FIG. 3b is a close-up rear view of the frame of FIG. 3a.

### DETAILED DESCRIPTION

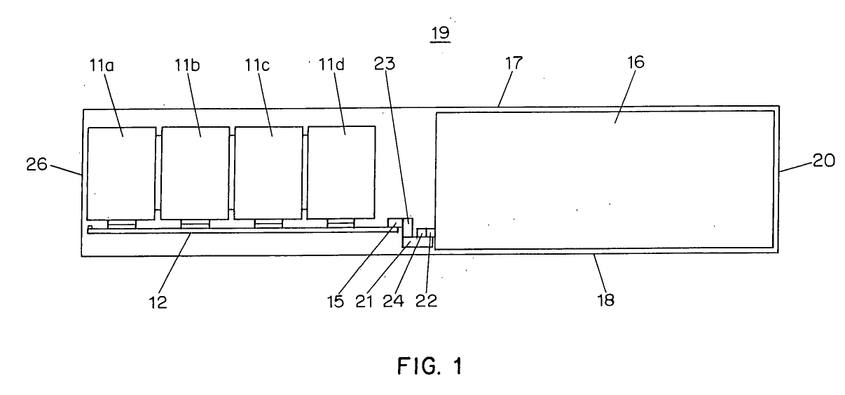

FIG. 1 shows a side cutaway view of an enclosure 19 according to the invention. The enclosure has a front face 26, a rear face 20, a top face 17 and a bottom face 18. Top and bottom faces 17 and 18 are typically featureless because they may face other equipment that is above or below in the rack. The rear face 20 has power and data connections (omitted for clarity in FIG. 1) and has openings for flow of cooling air, also omitted for clarity in FIG. 1.

In this figure, it is possible to see in edgewise view a centerplane 21 which is connected by means of connector 24 to a rearward connector 22 which connects to equipment 16. Equipment 16 may include fans, power supplies, controllers, and input/output (I/O) modules. Centerplane 21 also has a plurality of connectors 23, one for each frame, about which more will be said below.

A typical frame is visible in FIG. 1, carrying four disk drives 11a, 11b, 11c, and 11d. These four disk drives each contain at least one (and typically more than one) rotating platter. The platters rotate in the plane of FIG. 1. Each drive 11a, 11b, 11c, and 11d has a connector at the bottom of the drive (as oriented in FIG. 1) which plugs into a mating connector on printed circuit board (PCB) 12. PCB 12 has a connector 15 which connects to mating connector 23. PCB 12 has data concentrator circuitry which thereby reduces the pin count at connector 15.

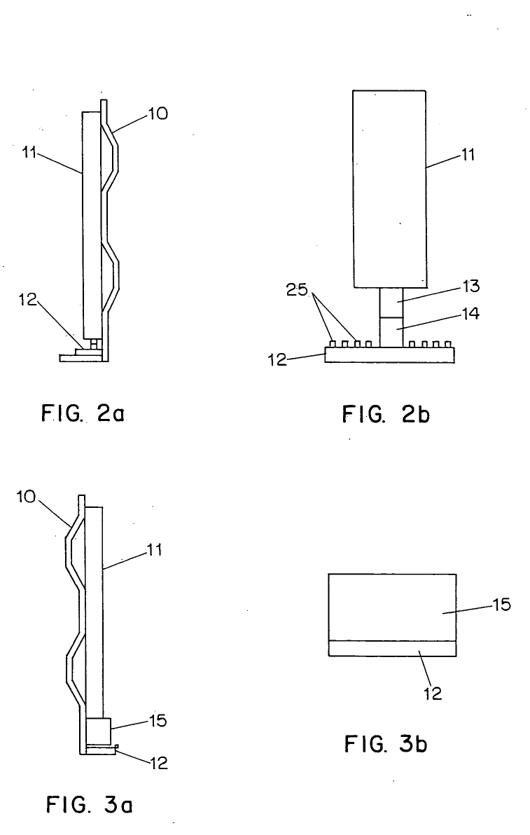

FIG. 2a is a front view of a frame 10 according to the invention. The frame is L shaped in FIG. 2a, with a vertical portion (typically of metal such as aluminum) more or less parallel to drive 11 and a horizontal portion. In some cases the horizontal portion may literally be the same as printed circuit board 12, but it is thought preferable that the horizontal portion include a strong portion (typically made of metal such as aluminum) that is affixed to the vertical portion or, preferably, is integrally formed with it.

FIG. 2b is a close-up front view of the frame 10 of FIG. 2a. A drive 11 may be seen. The drive 11 has a connector 13 for power and data. This connector 13 mates with a connector 14 of the PCB 12. (Those skilled in the art will appreciate that while these connectors 13, 14 are referred to in the singular as a connector, it does not deviate in any way from the invention if each drive 11 has two connectors, one for power and another for data.) One or more LEDs 25 are provided on the PCB 12, and as described below, are helpful in telling a user which drive 11 to replace.

In FIGS. 2a and 2b it will be appreciated that typically three other drives are parallel to the drive 11 portrayed in the figure, but are behind or in front of the drive and thus only one of the drives 11 is visible.

FIG. 3a is a rear view of a frame 10 according to the invention. The frame is L shaped just as in FIG. 2a, with the horizontal portion extending the opposite direction (to the right) due to the view being a rear view rather than the front view of FIG. 2a. The vertical portion may again be seen.

FIG. 3b is a close-up rear view of the frame 10 of FIG. 3a. The PCB 12 may be seen in an end view. The frame 10 has a connector 15 for power and data. This connector 15 mates with a connector 23 of the centerplane 21, as shown in FIG. 1.

In FIGS. 3a and 3b it will be appreciated that typically three other drives are parallel to the drive 11 portrayed in the figure, but are behind or in front of the drive and thus only one of the drives 11 is visible.

This arrangement consists of an “L” frame 10 allowing the placement of some number of drives 11 standing vertically in the frame 11 with connectors 13 facing down.

Optionally, these frames 10 can be doubled, that is, with two rows of hard drives, one row on one face of the vertical portion and a second row on the other face of the vertical portion. The “L” bracket is preferably embossed or ribbed to provide rigidity, as shown in FIG. 1.

There are at least two ways to make electrical connections of the hard drives 11 to the backplane or centerplane.

In a first system, the frame 10 (sometimes called a “cassette”) will consist of an L frame, concentrator logic, drive connectors, drive locator/error leds and an interface connector on a PCB 12 and hard drives 11. Each drive 11 will plug into this PCB 12. Each drive 11 will not require its own housing, but instead it will plug into the frame 10 and lock (click) into place in a tool-less fashion. Then the entire frame 10 will slide into the enclosure 19 and will then be cammed horizontally (to the right in FIG. 1) into a connector 23 mounted on the centerplane 21 at the end of the travel of the frame 10.

In a second system, the frame 10 will consist of all items just described in connection with the first system, and in addition there is a camming mechanism to accommodate vertical insertion. The frame 10 will slide into the enclosure 19 to the desired depth, and then then its connector 15 will be cammed vertically down to connector 23 on the backplane or centerplane 21. This can be accomplished with a rotating shaft cam mechanism, such as a dial.

With either of these systems, the backplane/centerplane 21 is optionally capable of being pulled out from the area 16 (see FIG. 1) by pulling it to the left in FIG. 1. This makes the backplane/centerplane 21 into a field-replaceable unit (FRU). Importantly, the backplane/centerplane 21 does not need to extend vertically from the top face 17 to the bottom face 18 as in prior-art designs, and thus it need not block airflow between the rear of the enclosure (e.g. equipment 16) and the front of the enclosure (e.g. drives 11). The backplane/centerplane 21 need not carry as much circuitry as in prior-art designs, because some data concentration can take place on each of the frames 10 within its PCB 12.

A faceplate may be provided at face 26. If so, then the faceplate is removeable as needed to gain access to frames 10. Alternatively, each frame 10 may have a bezel, and the bezels of the frames 10 may fill the relevant portion of the face 26.

As will be appreciated, this arrangement provides a mechanism to allow front loading of 2.5-inch drives 11 in a high drive density enclosure 19. It allows the backplane 21 to become a FRU (field replaceable unit). And it greatly enhances airflow through the enclosure 19 this arrangement permits the removal of more than one but less than all of the drives 11. In a typical arrangement, a single frame 10 carrying four drives 11 can be pulled out. A series of LEDs or other indicators 25 tells the user which drive 11 to replace.

In the event of centerplane 21 replacement in the field, pulling four drives at a time will facilitate and allow greater control of drive organization for re-insertion after the centerplane 21 has been replaced via sliding it out of the front of the enclosure 19.

Backplane 21 complexity is reduced as hard drive signal routing is spread across each frame's printed circuit board 12.

Some typical procedures will now be described.

In the event of failure or suspected failure of a drive, the user will observe the face 26 of the enclosure. An LED or other indicator will preferably indicate which frame 10 needs to be pulled. In addition, an LED or other indicator will preferably indicate which drive 11 of the frame 10 will need to be pulled. The user will make note of the LED indications. The user will pull the indicated frame 10 out of the enclosure 19, to the left in FIG. 1. In doing so, the user will separate connector 15 from its mating connector 23. Ideally the design of the system is such that this separation may be performed without disturbing the function of other frames 10 so that the enclosure and its drives may remain in service throughout.

Drives 11 of frame 10 are now accessible to the user. The user releases a snap latch and lifts a particular drive 11 vertically from the frame 10, having selected the drive 11 based upon the previously mentioned LED indications. In doing so, the drive's connector 13 is separated from its mating connector 14. A replacement drive 11 is inserted into place, with its connector 13 mating with connector 14, and the drive is snapped into place, thereby being mechanically secured to the frame 10 as well as electrically connected thereto.

frame 10 again having its full complement of drives, the user then inserts the frame 10 back into the enclosure 19. The connector 15 is re-engaged with the connector 23. The new drive is tested and put into service.

Importantly, in this way the user has removed more than one but less than all of the drives, and has then replaced what was removed.

It will be appreciated that while the arrangement is described with each drive 11 extending upwards from PCB 12, and while this is considered preferable, the system could be set up with each drive 11 extending downwards from PCB 12, without deviating from the ivention.

Described in different terms, the disk drive enclosure has a front, a rear, a left, a right, a top, and a bottom, the enclosure comprising a plurality of frames substantially parallel to each other and extending from the front of the enclosure toward the rear of the enclosure. Each frame has a rear, each frame comprising a plurality of disk drives, the disk drives substantially coplanar, each frame comprising a printed circuit board extending to the disk drives and extending to the rear of the frame and having a connector. Each frame printed circuit board is electrically connected with the plurality of disk drives by means of respective drive connectors. The enclosure further comprises a planar board extending from left to right, and having a respective connector for each frame connector connected to the each frame connector. Each frame printed circuit board comprises data concentrator logic such that the number of pins at the frame's rear connector is less than the sum of the number of pins at the drive connectors of the printed circuit board. The planar board preferably extends from left to right and connects to the rear of the enclosure by means of at least one connector and may be removed from the rear of the enclosure by disconnecting the connector.

Described in different terms, a removal and replacement procedure may be as follows. A failure or suspected failure in one of the drives is detected. A user views the enclosure from the front. The user selects one from among a plurality of carriers, the selected one of the carriers carrying the failed or suspected-failed drive and also carrying at least one additional drive but less than all of the multiplicity of disk drives. The user extracts the selected carrier from the enclosure by sliding it toward the front of the enclosure. The user removes the failed or suspected-failed drive from the selected carrier. The user inserts a different drive to the selected carrier. The user returns the selected carrier to the enclosure by sliding it toward the rear of the enclosure. In an exemplary embodiment, the step of removing the failed or suspected-failed drive from the selected carrier is performed by moving the drive parallel to the carrier, and upwards from the carrier, and comprises releasing a snap latch. When a different drive is inserted to the carrier, it is snapped into place.

The invention has been described with respect to particular embodiments. Those skilled in the art will effortlessly devise myriad obvious variations and improvements without departing in any way from the invention, all of which are intended to be encompassed within the claims which follow.

1. A disk drive enclosure having a front, a rear, a left, a right, a top, and a bottom, the enclosure comprising a plurality of frames substantially parallel to each other and extending from the front of the enclosure toward the rear of the enclosure;
each frame having a rear, each frame comprising a plurality of disk drives, the disk drives substantially coplanar, each frame comprising a printed circuit board extending to the disk drives and extending to the rear of the frame and having a connector;
each frame printed circuit board electrically connected with the plurality of disk drives by means of respective drive connectors;
the enclosure further comprising a planar board extending from left to right, and having a respective connector for each frame connector connected to the each frame connector;
each frame printed circuit board comprising data concentrator logic such that the number of pins at the frame's rear connector is less than the sum of the number of pins at the drive connectors of the printed circuit board.

2. The enclosure of claim 1 wherein the planar board extending from left to right connects to the rear of the enclosure by means of at least one connector and may be removed from the rear of the enclosure by disconnecting the connector.

3. A method for use with a disk drive enclosure having a front, a rear, a left face, a right face, a top, and a bottom, the enclosure containing a multiplicity of disk drives each having a platter spinning in a plane parallel to the left and right faces, the method comprising the steps of:
detecting a failure or suspected failure in one of the drives; the enclosure from the front;
selecting one from among a plurality of carriers, the selected one of the carriers carrying the failed or suspected-failed drive and also carrying at least one additional drive but less than all of the multiplicity of disk drives;
extracting the selected carrier from the enclosure by sliding it toward the front of the enclosure;
removing the failed or suspected-failed drive from the selected carrier;
inserting a different drive to the selected carrier; and
returning the selected carrier to the enclosure by sliding it toward the rear of the enclosure.

4. The method of claim 3 wherein the step of removing the failed or suspected-failed drive from the selected carrier is performed by moving the drive parallel to the carrier.

5. The method of claim 4 wherein the step of removing the failed or suspected-failed drive from the selected carrier is performed by moving the drive parallel to the carrier and upwards from the carrier.

6. The method of claim 4 wherein the step of removing the failed or suspected-failed drive from the selected carrier further comprises releasing a snap latch.

7. The method of claim 3 wherein the step of inserting a different drive to the selected carrier further comprises snapping the drive into place.
